(19) United States
(12) Patent Application Publication
(10) Pub. No.: US 2004/0129440 A1
(43) Pub. Date: Jul. 8, 2004

(54) Flame-retardant electric/electronic component excellent in contact stability

(76) Inventors: Hitoshi Hayashi, Kyoto (JP); Yoshiaki Taguchi, Shizuoka (JP)

Correspondence Address: BIRCH STEWART KOLASCH & BIRCH, PO BOX 747, FALLS CHURCH, VA, 22040-0747, US

(21) Appl. No.: 10/476,850

(22) PCT Filed: May 7, 2002
(86) PCT No.: PCT/JP02/04420

(30) Foreign Application Priority Data
May 8, 2001 (JP) 2001-137310

(51) Int. Cl. H05K 5/00

(52) U.S. Cl. 174/52.1

(57) ABSTRACT

The present invention relates to a nonflammable electric/electronic part, which is an electric/electronic part constituted by a nonflammable case part made from resin that generates phosphine and metal parts assembled in the case part, and at least one contact portion that controls an electric current is formed in the case part by the metal parts, and in this arrangement, the metal of the metal parts constituting the contact portion has a specific ideal standard electrode potential (−0.45 V to 0.80 V) and/or such a characteristic that a change in contact resistance values under a predetermined phosphine generating environment is not more than 25 mΩ (when the electric/electronic part is used up to a current of 5A) or not more than 50 mΩ (when the electric/electronic part is used from a current exceeding 5A up to a current of 30A).

### FIELD OF THE INVENTION

The present invention relates to a nonflammable electric/electronic part. More specifically, the present invention relates to an electric/electronic part having a contact portion such as a metal contact, and more particularly concerns a nonflammable electric/electronic part that has superior stability in contact resistance value.

### BACKGROUND ART

Electronic parts, such as relays and switches, have been formed by a thermosetting resin that is superior in its insulating property, heat resistance and dimension stability as its molding material, in order to ensure proper operation characteristics under severe environmental conditions such as temperature changes and the like.

However, the thermosetting resin is virtually incapable of recycling. Consequently, at the present circumstances in which there are strong demands for environmental safety, the use of the thermosetting resin incapable of recycling has raised problems.

In comparison with the thermoplastic resin, the thermosetting resin causes more resin dusts due to abrasion and separation. Such resin dusts tend to adhere to metal contacts, and cause adverse effects on functions of relays, switches and the like, resulting in adverse effects on reliability of the parts.

In order to solve the above-mentioned problems, polyester-based thermoplastic resins that are superior in recycling and low dust generation property have been utilized. In order to improve the nonflammable property of electronic parts, the resin composition is allowed to contain a halogen-based flame retarder. Upon burning, such a resin containing a halogen-based flame retarder generates halogen-based gases. When such a resin composition containing a halogen-based flame retarder is molded by a molding machine, the metal mold is susceptible to corrosion.

Therefore, at present, in order to avoid such problems of the generation of halogen gases and corrosion in the metal mold, thermoplastic resin compositions containing red phosphorus, phosphate, silicone or the like, that is, a non-halogen-based flame retarder, have been used.

However, when an electric/electronic part that is formed by using such a resin composition and has contact portions like metal contacts, for example, a relay or a switch, is used, in particular, under high temperature environments, the relay, switch or the like is damaged in its functions, and sometimes no longer functions properly.

### DISCLOSURE OF THE INVENTION

(Technical Problems to be Solved by the Invention)

The present invention has been devised to solve the above-mentioned problems, and its objective is to provide a nonflammable electric/electronic part which is free from generation of halogen gases upon burning, and has contact portions such as metal contacts that provide stable contact resistance values with a wide temperature range.

The inventors of the present invention have found that functional interventions in the above-mentioned relay, switch or the like using a resin composition containing red phosphorus are caused by phosphine generated from the red phosphorus contained in the resin composition as the flame retarder, and completed the present invention.

(Means to Solve the Problems)

The present invention relates to a nonflammable electric/electronic part, which is an electric/electronic part constituted by a nonflammable case part made from resin that generates phosphine and metal parts assembled in said case part, comprising:

at least one contact portion that controls an electric current, and is formed by the metal parts in the case part,

characterized in that the metal of the metal parts constituting the contact portion has a characteristic from not less than −0.45 V to not more than 0.80 V as an ideal standard electrode potential, and/or characterized in that the metal of the metal parts constituting the contact portion has a characteristic of not more than 25 mΩ in its change in contact resistance value in the case when the electric/electronic part is used up to a current of 5A and a characteristic of not more than 50 mΩ in its change in contact resistance value in the case when the electric/electronic part is used from a current exceeding 5A up to a current of 30A, when measured after a resin composition that generates phosphine of 0.1 to 1000 ppm at 150° C. for 24 hours and the metal parts constituting the contact portion have been left in a closed system having a volume of not more than 500 cm³ at 150° C. for 120 hours.

The resin that generates phosphine refers not to a halogen-based flame retarder as a flame retarder, but to a resin containing a phosphorus-based flame retarder such as red phosphorus, which generates phosphine (PH₃) under high-temperature environments. Examples of the resin to contain such a flame retarder include resin compositions such as polyethylene terephthalate, polybutylene terephthalate, polycarbonate, polyphenylene sulfide, ABS, polyphenylene oxide and epoxy resin. The above-mentioned phosphorus-based flame retarder (about 0.1 to 45 parts by weight) is added to 100 parts by weight of the resin so as to impart its nonflammable property.

When phosphine is generated, it adheres to the metal part as phosphoric acid. The adhesion of phosphoric acid intervenes with the electric contact function of the contact part that controls an electric flow. The present invention is directed to an electric/electronic part that is susceptible to such an intervention.

The nonflammable case part refers to a case part for an electric/electronic part, which is made from a resin containing the above-mentioned phosphorus-based flame retarder, and in the case, metal parts are assembled and at least one contact portion for controlling an electric current is formed by the metal parts. With respect to the electric/electronic part in which at least one contact portion is formed in the case part, examples thereof include a relay, a switch, a connector, a breaker and a contactor.

The contact portion for controlling an electric current refers to an electric contact at which a metal part is made contact with another metal part so that the on-off state of the contact controls an electric current flow (for example, a contact point and metal parts of a relay, a switch, a connector, a breaker and a contactor), or a metal part which controls an electric current flow with the contact and the metal part being maintained in a contact state (for example, a moving/fixed contact member, a moving/fixed contact terminal, a coil terminal, etc.).

In the present invention, the metal parts constituting such a contact portion for controlling an electric current is made of metal having a characteristic from not less than −0.45 V to not more than 0.80 V as an ideal standard electrode potential. In the present invention, the metal includes an alloy in addition to a metal element.

The ideal standard electrode refers to a standard electrode potential in an aqueous system (25° C.) of metal, and, for example, Chemical Handbook Basics II (3^{rd} Revised Edition)(Published by Maruzen Co., Ltd.) etc. is listed as reference. In the case of the application of an alloy, the value is obtained by adding each value obtained by multiplying each of rates of content (mole %) of the respective metals constituting the alloy by the standard electrode potential, and dividing the total by 100.

In the present invention, the metal parts constituting such a contact portion for controlling an electric current may be selected from those metals that have a characteristic of not more than 25 mΩ in its change in contact resistance value in the case when the electric/electronic part is used up to a current of 5A and a characteristic of not more than 50 mΩ in its change in contact resistance value in the case when the electric/electronic part is used from a current exceeding 5A up to a current of 30A, when measured after a resin composition that generates phosphine of 0.1 to 1000 ppm at 150° C. for 24 hours and the metal parts constituting the contact portion have been left in a closed system having a volume of not more than 500 cm³ at 150° C. for 120 hours. The closed system is not necessarily closed completely, and the above-mentioned contact resistance may be measured in a virtually closed state. The virtually closed state refers to a state in which, although the inside and the outside of a switch are not completely separated (blocked), the inside and outside case parts are isolated in such an extent that virtually no gas flow is generated inside the electric/electronic part such as a switch. The above-mentioned measurements are preferably carried out in a completely closed state; however, the measurement results obtained in the above-mentioned virtually closed state may be used.

In the present invention, the metal parts constituting a contact portion for controlling an electric current is made of metal that has a characteristic from not less than −0.45 V to not more than 0.80 V as an ideal standard electrode potential, and also has a characteristic of not more than 25 mΩ in its change in contact resistance value in the case when the electric/electronic part is used up to a current of 5A and a characteristic of not more than 50 mΩ in its change in contact resistance value in the case when the electric/electronic part is used from a current exceeding 5A up to a current of 30A, when measured after a resin composition that generates phosphine of 0.1 to 1000 ppm at 150° C. for 24 hours and the metal parts constituting the contact portion have been left in a closed system having a volume of not more than 500 cm³ at 150° C. for 120 hours.

In another aspect, the present invention provides the following method of use and method of selection:

With respect to metal forming metal parts to be used in an electric/electronic part made of a nonflammable case part made from a resin that generates phosphine and the metal parts that constitute at least a contact portion for controlling an electric current and are assembled in the case constituent parts, metal, which has a characteristic from not less than −0.45 V to not more than 0.80 V as an ideal standard electrode potential, is used.

With respect to the metal forming metal parts to be used in an electric/electronic part made of a nonflammable case part made from a resin that generates phosphine and the metal parts that constitute at least a contact portion for controlling an electric current and are assembled in the case constituent parts, a method of use or a method of selection of the metal is provided in which the metal has a characteristic of not more than 25 mΩ in its change in contact resistance value in the case when the electric/electronic part is used up to a current of 5A and a characteristic of not more than 50 mΩ in its change in contact resistance value in the case when the electric/electronic part is used from a current exceeding 5A up to a current of 30A, when measured after a resin composition that generates phosphine of 0.1 to 1000 ppm at 150° C. for 24 hours and the metal parts constituting the contact portion have been left in a closed system having a volume of not more than 500 cm³ at 150° C. for 120 hours.

With respect to the metal forming metal parts to be used in an electric/electronic part made of a nonflammable case part made from a resin that generates phosphine and the metal parts that constitute at least a contact portion for controlling an electric current and are assembled in the case constituent parts, a method of use or a method of selection of the metal is provided in which: the metal, which has a characteristic of not more than 25 mΩ in its change in contact resistance value in the case when the electric/electronic part is used up to a current of 5A and a characteristic of not more than 50 mΩ in its change in contact resistance value in the case when the electric/electronic part is used from a current exceeding 5A up to a current of 30A, when measured after a resin composition that generates phosphine of 0.1 to 1000 ppm at 150° C. for 24 hours and the metal parts constituting the contact portion have been left in a closed system having a volume of not more than 500 cm³ at 150° C. for 120 hours.

The electric/electronic part of the present invention, which has a structure in which an electric contact portion for controlling an electric current and the like is formed in a nonflammable case part made from a resin that generates phosphine, is free from generation of halogen gases upon burning to exhibit a superior nonflammable property, and less susceptible to functional damages due to an increase in contact resistance even when used in a wide temperature range, in particular, under high temperature environments.

The following description will discuss the present invention in detail by means of examples.

### EXAMPLES

Production of a Switch

Molding Material Containing Red Phosphorus

Polyethylene terephthalate having a intrinsic viscosity number of 0.75 (PET: made by Teijin Ltd.)(A) that had been hot-air dried at 130° C. for 8 hours, a master batch (PBT-M)(B) prepared by kneading 30% by weight of red phosphorus powder (Nova Excel 140 (containing red phosphorus ≧92%): made by Rinkagaku Kogyo Co., Ltd.) coated with thermosetting resin in polytetramethylene terephthalate (made by Teijin Ltd.) having a intrinsic viscosity number of 0.71, a crystallization accelerator (terminal blocked PEG)(KRM4004: made Sanyo Chemical Industries, Ltd.; polyethylene glycol (D) the terminal of which is blocked by benzoic acid), glass flakes (REF600A: made by Nippon Sheet Glass Co., Ltd.); maximum particle size 1700 μm, thickness 4 μm, aspect ratio 1/150 (E)) and glass fiber (T-124: made by Nippon Electric Glass Co., Ltd.), average fiber length 3 mm, average fiber diameter 13 μm, aspect ratio 230 (F)) were preliminarily mixed uniformly by a tumbler at rates (unit of parts by weight (except for content of red phosphorus represented by unit of % by weight)) shown in Table 1. Thereafter, the mixture was melt-kneaded by a twin-screw extruder with a bent having a screw diameter of 44 mm under conditions of a cylinder temperature of 270° C., screw number of revolutions of 100 rpm and an amount of discharge of 30 kg/hr, while being pressure-reduced to vacuum. The sled, discharged from a die, was cooled, and cut to obtain resin composition pellets.

TABLE 1

| | (B) | (C) | (D) | | |
|---|---|---|---|---|---|
| | Master batch | Content of red | Terminal | (E) | (E) |
| (A) | containing coated red | phosphorus in | blocked | Glass | Glass |
| PET | phosphorus powder | composition: % | PEG | flake | fiber |
| 100 | 25 | 3.0 | 7 | 75 | 25 |

Next, a cover (approximately 15×30×3 mm) and a case (approximately 15×30×10 mm) for an evaluation-use switch were molded with an injection molding machine having an injection capacity of 5 ounce by using these pellets under conditions of a cylinder temperature of 270° C., a metal mold temperature of 100° C., an injection pressure of 60 MPa, cooling time of 30 seconds and an entire molding cycle of 60 seconds. These cover and case generate approximately 4 ppm of phosphine at 150° C. for 24 hours.

An electric part having a contact portion for controlling an electric current is assembled by using each of 6 kinds of alloys having different properties as shown in Table 2. FIG. 1 shows a schematic structural drawing in which the contact portion for controlling an electric current is assembled in the above-mentioned case.

FIG. 1 is explained briefly. In the drawing, reference numeral 2 is a case. A contact portion, which controls an electric current, is formed in this case 2. Reference numeral 1 is a push button, and its end portion is made in contact with one end portion of a movable contact member 7 in the case 2. A movable contact 4 (having a contact shape of a size of the metal part of 2.5 mmφ and a height of 1.5 mm) is formed on the other end portion of the movable contact member 7 so that it is allowed to move and contact a fixed contact 5 formed on an end portion of a fixed contact terminal 3 inside the case through an action of a movable spring 6. In this arrangement, when the push button 1 is pressed, the movable contact member 7 is shifted downward so that the movable contact is shifted from an upper fixed contact 5a to a lower fixed contact 5b; thus, an electric current flowing toward the upper fixed terminal 3a is changed to flow toward a fixed terminal 3b in the center. The contact portion for controlling an electric current is constituted by a movable spring 6, the movable contact member 7 including the movable contact 4 and the fixed contacts 5a and 5b. The case having this contact portion for controlling an electric current is closed by the cover in a virtually tightly-closed state to assemble the evaluation-use switch. This evaluation-use switch corresponds to the electric/electronic part that is used in a range up to an electric current of 5A.

The evaluation-use switch is left under a temperature environment of 150° C. for 120 hours. A difference in contact resistance values before and after the heating treatment and the amount of adhesion of phosphoric acid to the contact after the heating treatment were measured.

The contact resistance value was measured as a contact resistance value obtained when a contact resistance meter (milliohm meter) was connected between each pair of the fixed terminals of the switch and the circuit was closed. Table 2 shows the results of the measurements.

The above-mentioned measurements of contact resistance correspond to measurements of a change in contact resistance value obtained after a resin composition (including a molded product) that generates phosphine of 1 ppm per 1 g at 150° C. for 24 hours and the metal parts constituting the contact portion have been left in a closed system having a volume of about 4.5 cm³ at 150° C. for 120 hours.

The measurements of the amount of generation of phosphine from the switch molded product were carried out in the following manner: The switch molded product (case, cover) was put into a 4-L flask with a septum, and tightly closed, and left at 150° C. for 24 hours. After 24 hours, the container was cooled to room temperature with the container being tightly closed. A syringe and a phosphine detecting tube (made by Gastech Service Inc.; 7LA, 7L, 7) were connected to the septum to measure the amount of generation of phosphine in the container so that the amount of generation per 1 g was calculated from the following calculating equation:

Amount of generation of phosphine y(μg/g)=Indicated value of Gas detecting tube (ppm)×(0.004 m³)×(1380 g/m³)÷Weight of resin (g)

The amount of adhesion of phosphoric acid was detected in the following manner. A movable contact member 7 including the movable contact 4 and a fixed contact (metal contact) including fixed contacts 5a, 5b were cut out, and put into a glass bottle containing 1.5 ml of pure water to be subjected to a washing treatment by an ultrasonic washing device for about 5 minutes. The washing solution was put into an ion chromatographic analyzer to carry out qualitative and quantitative measurements on phosphoric acid. Table 2 shows the results of the measurements.

TABLE 2

| | | | | | | | | | | | Difference of |
|---|---|---|---|---|---|---|---|---|---|---|---|
| Mole % | | | | | | | | | Ideal | Amount of | resistance values/ |
| Example/ | | | | | | | | | standard | adhesion of | mΩ of contact |
| Comparative | | | | | | | | | electrode | phosphoric acid | before and after |
| Example | Au | Pd | Ag | Ni | Cd | In | Sn | O | potential/V | at contact ppm | thermal treatment |
| Standard electrode | 1.68 | 0.915 | 0.7991 | −0.228 | −0.4019 | −0.3382 | −0.138 | −0.563 | — | — | — |
| potential/V of | | | | | | | | | | | |
| aqueous system | | | | | | | | | | | |
| (25° C.) of | | | | | | | | | | | |
| each component | | | | | | | | | | | |
| Sample 1 | 0 | 0 | 75.3 | 0 | 7.4 | 0 | 0 | 17.3 | 0.4746 | 3.2 | 6.7 |
| Sample 2 | 0 | 0 | 75.6 | 0 | 0 | 1.6 | 5.5 | 17.4 | 0.4932 | 25 | 4.8 |
| Sample 3 | 0 | 0 | 100 | 0 | 0 | 0 | 0 | 0 | 0.7991 | 100 | 17.9 |
| Sample 4 | 0 | 100 | 0 | 0 | 0 | 0 | 0 | 0 | 0.915 | 190 | 455 |
| (for comparison) | | | | | | | | | | | |
| Sample 5 | 100 | 0 | 0 | 0 | 0 | 0 | 0 | 0 | 1.680 | 260 | 2000 |
| (for comparison) | | | | | | | | | | | |
| Sample 6 | 0 | 0 | 83 | 17 | 0 | 0 | 0 | 0 | 0.6245 | 80 | 25.2 |

### BRIEF DESCRIPTION OF THE DRAWINGS

FIG. 1 is a schematic cross-sectional view of a switch, which is used for explaining a contact portion for controlling an electric current.

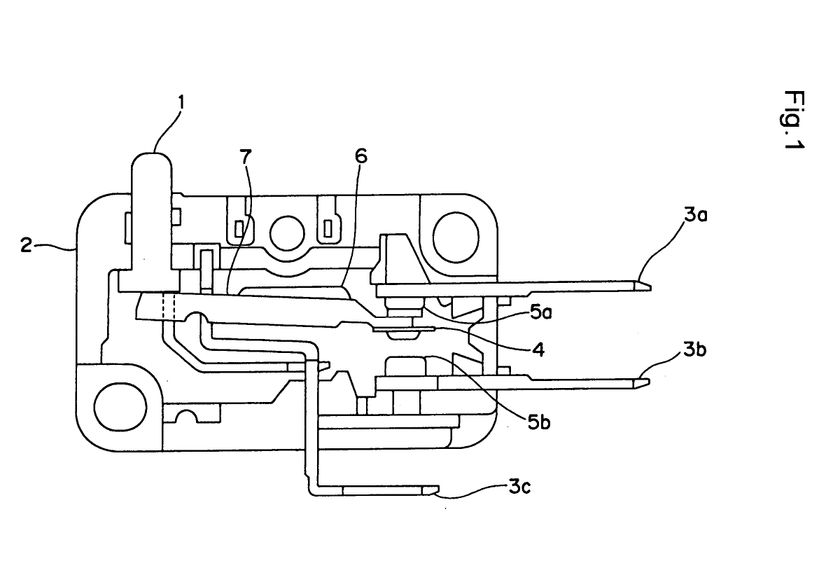

1. A nonflammable electric/electronic part, which is an electric/electronic part constituted by a nonflammable case part made from resin that generates phosphine and metal parts assembled in said case part, comprising:
at least one contact portion that controls an electric current, and is formed by the metal parts in the case part,
characterized in that the metal of the metal parts constituting the contact portion has a characteristic from not less than −0.45 V to not more than 0.80 V as an ideal standard electrode potential.

2. A method of use of metal, characterized in that, with respect to metal forming metal parts to be used in an electric/electronic part made of a nonflammable case part made from a resin that generates phosphine and the metal parts that constitute at least a contact portion for controlling an electric current and are assembled in the case constituent parts, metal, which has a characteristic from not less than −0.45 V to not more than 0.80 V as an ideal standard electrode potential, is used.

3. A nonflammable electric/electronic part which is an electric/electronic part constituted by a nonflammable case part made from resin that generates phosphine and metal parts assembled in said case part, comprising:
at least one contact portion that controls an electric current, and is formed by the metal parts in the case part,
characterized in that the metal of the metal parts constituting the contact portion has a characteristic of not more than 25 mΩ in its change in contact resistance value in the case when the electric/electronic part is used up to a current of 5A and a characteristic of not more than 50 mΩ in its change in contact resistance value in the case when the electric/electronic part is used from a current exceeding 5A up to a current of 30A, when measured after a resin composition that generates phosphine of 0.1 to 1000 ppm at 150° C. for 24 hours and the metal parts constituting the contact portion have been left in a closed system having a volume of not more than 500 cm³ at 150° C. for 120 hours.

4. A method of use of metal, characterized in that, with respect to metal forming metal parts to be used in an electric/electronic part made of a nonflammable case part made from a resin that generates phosphine and the metal parts that constitute at least a contact portion for controlling an electric current and are assembled in the case constituent parts, the metal has a characteristic of not more than 25 mΩ in its change in contact resistance value in the case when the electric/electronic part is used up to a current of 5A and a characteristic of not more than 50 mΩ in its change in contact resistance value in the case when the electric/electronic part is used from a current exceeding 5A up to a current of 30A, when measured after a resin composition that generates phosphine of 0.1 to 1000 ppm at 150° C. for 24 hours and the metal parts constituting the contact portion have been left in a closed system having a volume of not more than 500 cm³ at 150° C. for 120 hours.

5. A nonflammable electric/electronic part, which is an electric/electronic part constituted by a nonflammable case part made from resin that generates phosphine and metal parts assembled in said case part, comprising:
at least one contact portion that controls an electric current, and is formed by the metal parts in the case part,
characterized in that the metal of the metal parts constituting the contact portion has a characteristic from not less than −0.45 V to not more than 0.80 V as an ideal standard electrode potential, and also has a characteristic of not more than 25 mΩ in its change in contact resistance value in the case when the electric/electronic part is used up to a current of 5A and a characteristic of not more than 50 mΩ in its change in contact resistance value in the case when the electric/electronic part is used from a current exceeding 5A up to a current of 30A, when measured after a resin composition that generates phosphine of 0.1 to 1000 ppm at 150° C. for 24 hours and the metal parts constituting the contact portion have been left in a closed system having a volume of not more than 500 cm³ at 150° C. for 120 hours.

6. A method of use of metal, characterized in that, with respect to metal forming metal parts to be used in an electric/electronic part made of a nonflammable case part made from a resin that generates phosphine and the metal parts that constitute at least a contact portion for controlling an electric current and are assembled in the case constituent parts, the metal of the metal parts constituting the contact portion has a characteristic of not more than 25 mΩ in its change in contact resistance value in the case when the electric/electronic part is used up to a current of 5A and a characteristic of not more than 50 mΩ in its change in contact resistance value in the case when the electric/electronic part is used from a current exceeding 5A up to a current of 30A, when measured after a resin composition that generates phosphine of 0.1 to 1000 ppm at 150° C. for 24 hours and the metal parts constituting the contact portion have been left in a closed system having a volume of not more than 500 cm³ at 150° C. for 120 hours.
